(19) United States
(12) Patent Application Publication
(10) Pub. No.: US 2017/0194590 A1
(43) Pub. Date: Jul. 6, 2017

(54) ORGANIC EL ELEMENT AND ORGANIC EL LIGHT EMITTING APPARATUS

(71) Applicant: JOLED INC., Tokyo (JP)

(72) Inventors: Hirofumi FUJITA, Osaka (JP); Shinya FUJIMURA, Osaka (JP); Satoru OHUCHI, Hyogo (JP); Yoshiaki TSUKAMOTO, Shiga (JP)

(73) Assignee: JOLED INC., Tokyo (JP)

(21) Appl. No.: 15/313,330

(22) PCT Filed: May 26, 2015
(86) PCT No.: PCT/JP2015/002667

§ 371 Date: Nov. 22, 2016

(30) Foreign Application Priority Data
May 30, 2014 (JP) 2014-113549

(51) Int. Cl. H01L 51/50; H01L 51/52

(52) U.S. Cl. CPC H01L 51/5088; H01L 51/5206; H01L 51/5221; H01L 51/5056; H01L 51/5012; H01L 51/5096; H01L 2251/303; H01L 51/0039

(57) ABSTRACT

An organic EL element includes an anode and a cathode that are disposed at opposed positions, a functional layer and a hole injection layer that are stacked between the anode and the cathode, the functional layer containing an organic material, and the hole injection layer being for injecting holes into the functional layer. The hole injection layer includes a transition metal oxide as a main component, and contains at least one of Al and Mg.

### TECHNICAL FIELD

The present disclosure relates to an organic electroluminescent device (hereinafter referred to as “organic EL element”), which is an electrically light-emitting element.

### BACKGROUND ART

In recent years, research and development has been carried out for various types of functional elements using organic semiconductors. A typical example of the functional elements is an organic EL element. The organic EL element is a current driven-type light emitting element and has a configuration in which a functional layer is provided between an electrode pair composed of an anode and a cathode, the functional layer including a light emitting layer made of an organic material. Then, voltage is applied across the electrode pair so as to recombine holes injected into the functional layer from the anode and electrons injected into the function layer from the cathode. The organic EL element emits light by an electroluminescence phenomenon generated by the recombination, Since the organic EL element is self-luminous and thus provides high visibility, and is a solid-state element and thus provides excellent resistance to vibration, attention is given to the application of the organic EL element as a light emitting element or a light source in various types of display apparatuses.

With the organic EL element, in order to provide highly bright light emission with low power consumption, it is important not only to provide a high internal quantum efficiency by efficiently injecting carriers (holes and electrons) from the electrodes to the functional layer, but also to efficiently extract light generated by the injected carriers to the outside of the element.

In general, in order to efficiently inject carriers, it is effective to provide an injection layer between the functional layer and each electrode so as to reduce the energy barrier at the time of injection. Among the injection layers, a hole injection layer provided between the functional layer and the anode is formed by using a conductive polymer such as PEDOT (conductive polymer), or a metal oxide such as nickel oxide (NiOₓ) or molybdenum oxide (MoOₓ) (see Patent Literature (PTL) 1 and Non Patent Literature (NPL) 1). Also, an electron injection layer provided between the functional layer and the cathode is formed by using an organic material such as a metal complex or oxadiazole, a metal such as barium, or an ionic crystal such as sodium fluoride.

### CITATION LIST

### Patent Literature

### [PTL 1]

Japanese Unexamined Patent Application Publication No. 2005-190998

### [PTL 2]

Japanese Unexamined Patent Application Publication No. H5-163488

### Non Patent Literature

### [NPL 1]

Shizuo Tokito et al., Journal of Physics, Volume 29 (1996) 11

### [NPL 2]

I-Min Chan et al., Thin Solid Films, 450 (2004) 304-311

### SUMMARY OF INVENTION

### Technical Problem

in order to use a NiOₓ film that is effective for reducing the energy barrier (hole injection barrier) during hole injection as described above as a practically usable hole injection layer, it is necessary to solve the problem of improving a light extraction efficiency for extracting light to the outside of the element caused by low light transmittance of the NiOₓ film.

To address this, for example, in NPL 2, an attempt is made to perform patterning to form a NiOₓ film in a striped pattern so as to extract light through the gaps of the stripes of the NiOₓ film. However, the light mission by the carriers injected from the deposited portion of NiOₓ is absorbed by the NiOₓ film itself. Accordingly, the light extraction efficiency is not sufficiently improved by the technique disclosed in NPL 2.

Under the circumstances, the present disclosure has been made in view of the problems described above, and it is an object of the present disclosure to provide an organic EL element and an organic EL light emitting apparatus that have a high light extraction efficiency.

### Solution to Problem

In order to achieve the above object, an organic EL element according to one aspect of the present disclosure includes: an anode and a cathode that are disposed at opposed positions; and a functional layer and a hole injection layer that are stacked between the anode and the cathode, the functional layer containing an organic material, and the hole injection layer being for injecting holes into the functional layer, wherein the hole injection layer includes a transition metal oxide as a main component, and contains at least one of Al and Mg.

### Advantageous Effects of Invention

According to the present disclosure, it is possible to provide an organic EL element and an organic EL light emitting apparatus that have a high light extraction efficiency.

### BRIEF DESCRIPTION OF DRAWINGS

FIG. 1 is a schematic cross-sectional view showing an example of a configuration of an organic EL element according to an embodiment.

FIG. 2A is a cross-sectional view showing a step of forming an anode in a method for producing an organic EL element according to the embodiment.

FIG. 2B is a cross-sectional view showing a step of forming a hole injection layer in the method for producing an organic EL element according to the embodiment.

FIG. 2C is a cross-sectional view showing a step of forming a buffer layer in the method for producing an organic EL element according to the embodiment.

FIG. 2D is a cross-sectional view showing a step of forming a light emitting layer in the method for producing an organic EL element according to the embodiment.

FIG. 2E is a cross-sectional view showing a step of forming a cathode in the method for producing an organic EL element according to the embodiment.

FIG. 3 is a diagram showing examples of Al content in the hole injection layer according to the embodiment.

FIG. 4 is a diagram showing the transmittance of NiOₓ films having a thickness of 10 nm according to the embodiment.

FIG. 5 is a schematic cross-sectional view showing an example of a configuration of a hole-only element according to the embodiment.

FIG. 6 is a device characteristics diagram showing a relationship between applied voltage and current density of hole-only elements according to the embodiment.

FIG. 7 is a diagram showing drive voltages for different Al contents of hole injection layers included in the hole-only elements according to the embodiment.

FIG. 8A conceptually shows an energy diagram at an interface between a functional layer and a NiOₓ film that does not contain Al according to the embodiment.

FIG. 8B conceptually shows an energy diagram at an interface between a functional layer and a NiOₓ film that contains Al according to the embodiment.

FIG. 9 is a diagram illustrating a relationship between aluminum and magnesium according to the embodiment.

FIG. 10A is a schematic perspective view of a lighting apparatus that is an example of an organic EL light emitting apparatus according to an embodiment.

FIG. 10B is a schematic perspective view of a display apparatus that is an example of an organic EL light emitting apparatus according an embodiment.

### DESCRIPTION OF EMBODIMENTS

### (Summary of Present Disclosure)

An organic EL element according to one aspect of the present disclosure includes: an anode and a cathode that are disposed at opposed positions; and a functional layer and a hole injection layer that are stacked between the anode and the cathode, the functional layer containing an organic material, and the hole injection layer being for injecting holes into the functional layer, wherein the hole injection layer includes a transition metal oxide as a main component, and contains at least one of Al and Mg.

Here, the band gap of the hole injection layer depends on the band gap of the transition metal oxide that is the main component of the hole injection layer, but the band gap can be increased by containing at least one of Al and Mg. As a result of the band gap of the hole injection layer being increased, it is possible to suppress absorption of light passing through the hole injection layer and enhance the transmittance. Accordingly, the transmittance of light passing through the hole injection layer can be enhanced and the light extraction efficiency can be enhanced.

Also, as a result of at least one of Al and Mg being contained, the band gap of the hole injection layer is increased, and the difference in energy level between the valence band of the hole injection layer and the HOMO (Highest Occupied Molecular Orbital) of the functional layer is reduced. Accordingly, the hole injection barrier between the hole injection layer and the functional layer is reduced, and the hole injection efficiency for injecting holes from the hole injection layer to the functional layer can be enhanced.

Based on the foregoing, with the organic EL element according to the present aspect, it is possible to achieve a high light extraction efficiency with low power consumption.

Also, for example, the transition metal oxide may be a nickel oxide, and the number of Al atoms contained in the hole injection layer may be 20% or less of the total number of atoms constituting the hole injection layer.

With this configuration, the hole injection efficiency can be enhanced and the light transmittance can be enhanced as compared to the case where Al is not contained at all. If Al is contained in an amount more than necessary, it is considered that the electric resistance of the hole injection layer increases to in turn reduce the hole injection efficiency. For this reason, as a result of the Al content being set to 20% or less, it is possible to enhance the hole injection efficiency while enhancing the light transmittance.

Also, for example, the number of Al atoms contained in the hole injection layer may be 15% or less of the total number of atoms constituting the hole injection layer.

With this configuration, as a result of the Al content being set to 15% or less, it is possible to enhance the hole injection efficiency while enhancing the light transmittance. For example, the improvement of the light transmittance and the improvement of the hole injection efficiency can be achieved with a good balance.

Also, for example, the transition metal oxide may be a nickel oxide, and the number of Mg atoms contained in the hole injection layer may be 24% or less of the total number of atoms constituting the hole injection layer.

With this configuration, the hole injection efficiency can be enhanced and the light transmittance can be enhanced as compared to the case where Mg is not contained at all. If Mg is contained in an amount more than necessary, it is considered that the electric resistance of the hole injection layer increases to in turn reduce the hole injection efficiency. For this reason, as a result of the Mg content being set to 24% or less, it is possible to enhance the hole injection efficiency while enhancing the light transmittance.

Also, for example, the number of Mg atoms contained in the hole injection layer may be 18% or less of the total number of atoms constituting the hole injection layer.

With this configuration, as a result of the Mg content being set to 18% or less, it is possible to enhance the hole injection efficiency while enhancing the light transmittance. For example, the improvement of the light transmittance and the improvement of the hole injection efficiency can be achieved with a good balance.

Also, for example, the transition metal oxide may contain transition metal that is at least one of Sc, Ti, V, Cr, Mn, Fe, Co, Ni, Cu, Zr, Hf, Nb, Ta, Mo and W.

With this configuration, various transition elements can be used, and thus usability can be enhanced.

Also, for example, the organic material may be an amine material.

Here, in organic amine molecules, the electron density of HOMO is distributed about an unshared electron pair of nitrogen atom, and thus this portion serves as a hole injection site. Accordingly, as a result of the functional layer containing an amine material, a hole injection site can be formed on the functional layer side. Accordingly, the holes transmitted from the hole injection layer can be efficiently injected into the functional layer.

Also, for example, the functional layer may be at least one of a hole transporting layer that transports the holes, a light emitting layer that emits light by recombination of the holes and electrons, and a buffer layer that is used to adjust optical characteristics or block electrons.

With this configuration, the hole injection efficiency for injecting holes into various types of functional layers can be enhanced irrespective of the type of functional layer.

Also, for example, an organic EL light emitting apparatus according to one aspect of the present disclosure includes an organic EL element configured as described above.

With this configuration, it is possible to constitute an organic EL panel, an organic EL lighting apparatus, an organic EL display apparatus and the like that provide the same effects as those described above.

Hereinafter, embodiments will be described specifically with reference to the drawings.

Note that the embodiments described below show general or specific examples of the present disclosure. Accordingly, the numerical values, shapes, materials, structural elements, the arrangement and connection of the structural elements, steps, the order of the steps, and the like shown in the following embodiments are merely examples, and therefore do not limit the scope of the present disclosure. Accordingly, among the structural elements described in the following embodiments, structural elements not recited in any one of the independent claims are described as arbitrary structural elements.

Note that the components shown in the diagrams are not true to scale.

### Embodiment

### [Configuration of Organic EL Element]

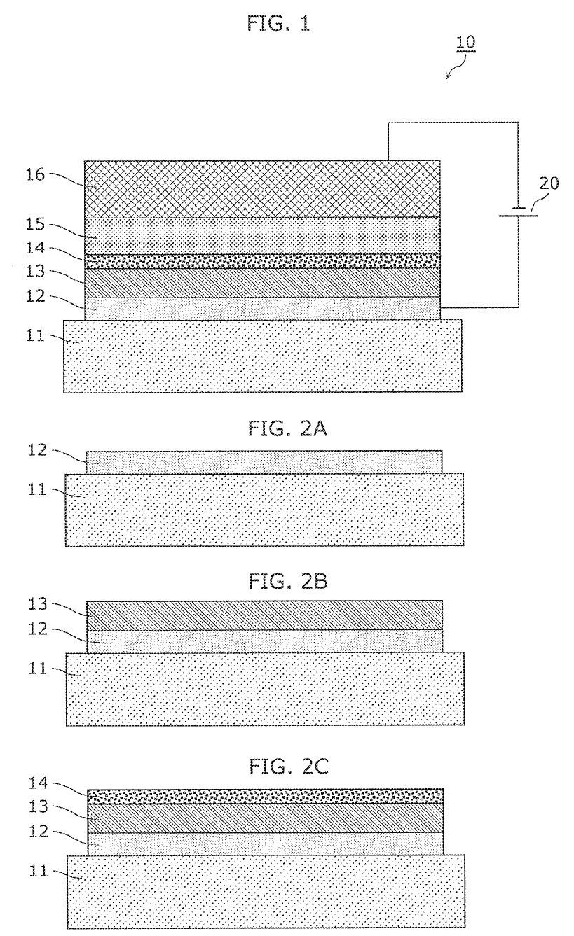

First, a configuration of an organic EL element according to an embodiment of the present disclosure will be described with reference to FIG. 1. FIG. 1 is a schematic cross-sectional view showing a configuration of an organic EL element 10 according to the present embodiment.

The organic EL element 10 is, for example, an applied-type organic EL element produced by applying a functional layer by a wet process. The organic EL element 10 has a configuration in which a stack of a hole injection layer 13 and various types of functional layers containing organic materials and having predetermined functions is provided between an electrode pair composed of an anode 12 and a cathode 16. In the present embodiment, the organic EL element 10 is a bottom emission type organic EL element that emits light in the downward direction on the sheet of FIG. 1, or in other words, on the side where a substrate 11 is provided.

To be specific, as shown in FIG. 1, the organic EL element 10 includes a substrate 11, an anode 12, a hole injection layer 13, a buffer layer 14, a light emitting layer 15 and a cathode 16. The organic EL element 10 is configured by stacking the anode 12, the hole injection layer 13, the buffer layer 14 (an example of a functional layer), the light emitting layer 15 (an example of a functional layer) and the cathode 16 in this order on one major surface of the substrate 11. The anode 12 and the cathode 16 are connected to a direct current power source 20 so that power is supplied to the organic EL element 10 from the outside.

Hereinafter, the layers constituting the organic EL element 10 will be described.

### [Substrate]

The substrate 11 is a portion serving as the base of the organic EL element 10, and is for example a light transmitting substrate having a light transmittance property. For example, the substrate 11 is a glass substrate, a resin substrate or the like. To be specific, the substrate 11 can be formed by using any of the following insulating materials: alkali-free glass, soda glass, fluorescence-free glass, phosphate glass, borate glass, quartz, acrylic resin, styrene resin, polycarbonate resin, epoxy resin, polyethylene, polyester, silicone resin, alumina and the like.

Although not shown in the diagrams, a thin film transistor (TFT) for driving the organic EL element 10 is formed on the surface of the substrate 11.

### [Anode]

The anode 12 is an electrode layer provided on the substrate 11, and is formed, for example, above the TFT via a planarization film or the like. The anode 12 is made of, for example, a conductive material having a light transmittance property. The anode 12 is made of, for example, indium tin oxide (ITO), indium zinc oxide (IZO), aluminum-doped zinc oxide (AZO) or the like. As an example, the anode 12 is an ITO thin film having a thickness of 50 nm.

### [Hole Injection Layer]

The hole injection layer 13 is a layer for injection holes into the functional layer. The hole injection layer 13 includes a transition metal oxide as a main component, and contains at least one of Al and Mg.

In the present embodiment, the hole injection layer 13 contains only Al among Al and Mg, and does not contain Mg. To be specific, the hole injection layer 13 is a 10 nm thick oxide film containing NiOₓ as a main component, and contains Al. The number of Al atoms contained in the hole injection layer 13 is 20% or less of the total number of atoms (Ni, O, Al) constituting the hole injection layer 13, and desirably 15% or less.

As a result of the organic EL element 10 including the hole injection layer 13 having an Al content as described above, the organic EL element 10 can sufficiently reduce the hole injection barrier at the interface between the hole injection layer 13 and the functional layer (buffer layer 14) and allows visible light to pass therethrough. Details of the hole injection efficiency and the light transmittance will be described later.

The content of an element is the atomic ratio (composition ratio) of the element. To be specific, the content refers to the proportion of the number of atoms of the element contained in the hole injection layer 13 with respect to the total number of atoms constituting the hole injection layer 13.

### [Functional Layer (Buffer Layer and Light Emitting Layer)]

The organic EL element 10 includes one or more functional layers that provide necessary functions required by the organic EL element 10. The functional layer according to the present embodiment is an organic functional layer containing an organic material. The functional layer and the hole injection layer 13 are stacked between the anode 12 and the cathode 16.

For example, the functional layer is at least one of a hole transporting layer that transports holes, a light emitting layer that emits light by recombination of holes and electrons, and a buffer layer that is used to adjust optical characteristics or block electrons. Alternatively, the functional layer is a layer in which two or more of the above layers are combined, or a layer including all of the above layers. In the present embodiment, an example will be described in which the organic EL element 10 includes the buffer layer 14 and the light emitting layer 15 as the functional layers.

The buffer layer 14 is a layer used to adjust optical characteristics or block electrons. For example, by forming the buffer layer 14 so as to have a thickness designed to have an appropriate value, it is possible to adjust the optical path length for light emitted from the light emitting layer 15 and suppress light interference and the like. Also, the buffer layer 14 functions as an electron barrier that suppresses a situation in which electrons injected from the cathode 16 reach the anode 12 without recombining with holes within the light emitting layer 15.

The buffer layer 14 contains, for example, an amine material. To be specific, the buffer layer 14 is made of a 20 nm thick organic amine polymer, namely, TFB (poly(9,9-di-n-octylfluorene-alt-(1,4-phenylene-((4-sec-butylphenyl)imino)-1,4-phenylene))).

As a result of the buffer layer 14 being made of an organic amine polymer, the holes transmitted from the hole injection layer 13 can be efficiently injected into a functional layer formed above the buffer layer 14. That is, in organic amine molecules, the electron density of HOMO is distributed about an unshared electron pair of nitrogen atom, and thus this portion serves as a hole injection site. Accordingly, as a result of the buffer layer 14 containing organic amine molecules, it is possible to form a hole injection site on the buffer layer 14 side.

The light emitting layer 15 is an organic functional layer that emits light by recombination of holes and electrons. For example, the light emitting layer 15 may emit light of any one of red, green and blue. Alternatively, the light emitting layer 15 may emit white light produced by three different colors of dopant dyes, namely, red, green and blue dopant dyes being doped.

For example, the light emitting layer 15 is made of a 70 nm thick organic polymer, namely, F8BT (poly(9,9-di-n-octylfluorene-alt-benzothiadiazole)). The material constituting the light emitting layer 15 is not limited thereto, and the light emitting layer 15 can be made by containing a known organic material. For example, the following materials that are disclosed in PTL 2 can be used: an oxinoid compound, a perylene compound, a coumarin compound, an azacoumarin compound, an oxazole compound, an oxadiazole compound, a perinone compound, a pyrrolopyrrole compound, a naphthalene compound, an anthracene compound, a fluorene compound, a fluoranthene compound, a tetracene compound, a pyrene compound, a coronene compound, a quinolone compound and an azaquinolone compound, a pyrazoline derivative and a pyrazolone derivative, a rhodamine compound, a chrysene compound, a phenanthrene compound, a cyclopentadiene compound, a stilbene compound, a diphenylquinone compound, a styryl compound, a butadiene compound, a dicyanomethylene pyran compound, a dicyanomethylene thiopyran compound, a fluorescein compound, a pyrylium compound, a thiapyrylium compound, selenapyrylium compound, a telluropyrylium compound, an aromatic aldadiene compound, an oligophenylene compound, a thioxanthene compound, a cyanin compound, an acridine compound, a metal complex of a 8-hydroxyquinoline compound, a metal complex of a 2-bipyridine compound, a complex between a Schiff base and a Group III metal, an oxine metal complex, a fluorescent material such as a rare earth complex, and the like.

### [Cathode]

The cathode 16 is an electrode layer provided on the opposite side of the substrate 11, and is formed, for example, on the light emitting layer 15. The cathode 16 and the anode 12 are disposed at opposed positions to each other. For example, the cathode 16 reflects light emitted from the light emitting layer 15 so as to cause the light to exit through the light emitting surface (substrate 11).

For example, the cathode 16 contains a metal material such as aluminum, silver or magnesium. As an example, the cathode 16 is made of a Mg—Ag alloy having a thickness of 50 nm.

### [Method for Producing Organic EL Element]

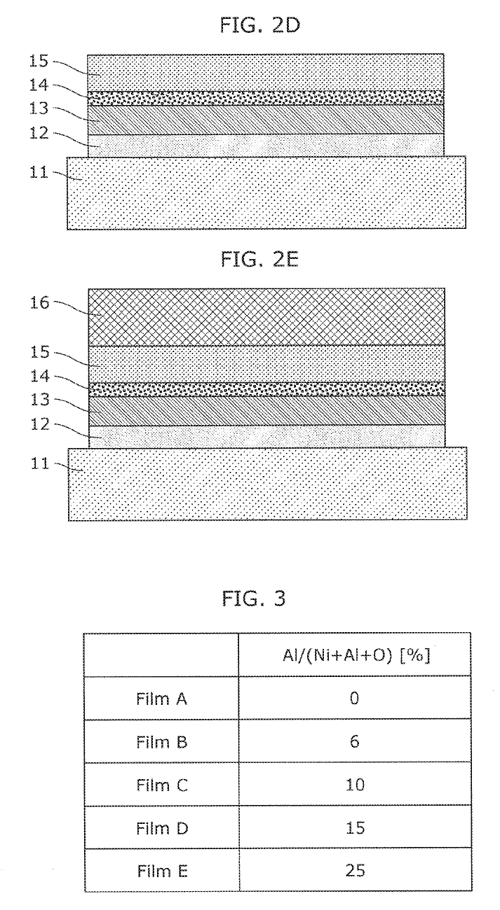

An example of an overall method for producing an organic EL element 10 will be described next with reference to FIGS. 2A to 2E. FIGS. 2A to 2E are cross-sectional views showing steps in the method for producing an organic EL element 10 according to the present embodiment.

First, a substrate 11 is placed in a chamber of a sputter deposition apparatus. Then, a predetermined sputtering gas is introduced into the chamber, and a 50 nm thick anode 12 made of ITO is formed on the substrate 11 based on a reactive sputtering method as shown in FIG. 2A.

Next, as shown in FIG. 26, a hole injection layer 13 is deposited on the anode 12. For example, it is preferable to deposit the hole injection layer 13 by a sputtering method with which a uniform film can be easily formed over a large area. To be specific, an appropriate amount of NiO sintered compact is disposed above an Al target, and necessary amounts of an argon gas serving as a sputtering gas and an oxygen gas serving as a reactive gas are introduced into the chamber. In this state, a high voltage is applied to ionize argon to impinge on the target. At this time, Ni particles and Al particles released by the sputtering phenomenon react with the oxygen gas, and a NiOₓ film containing an appropriate amount of Al is deposited on the anode 12. The details of the deposition condition will be described later with reference to FIG.

Next, as shown in FIG. 2C, a buffer layer 14 is formed on the hole injection layer 13. For example, a composition ink containing an organic amine molecule material is dropped on the surface of the hole injection layer 13 by a wet process that uses, for example, a spin coating method or an ink jet method, and after that, the solvent is volatilized and removed. With this configuration, the buffer layer 14 is formed.

Next, as shown in FIG. 2D, a light emitting layer 15 is formed on the buffer layer 14. For example, in the same manner, a composition ink containing an organic light emissive material is dropped on the surface of the buffer layer 14, and after that, the solvent is volatilized and removed. With this configuration, the light emitting layer 15 is formed.

The method for forming the buffer layer 14 and the light emitting layer 15 is not limited thereto, and the ink may be dropped or applied by using, other than the methods such as a spin coating method and an ink jet method, a known method such as, for example, a gravure printing method, a dispenser method, a nozzle coating method, intaglio printing or letterpress printing.

Subsequently, as shown in FIG. 2E, a cathode 16 is formed on the light emitting layer 15. For example, a Mg—Ag alloy is deposited on the surface of the light emitting layer 15 by a vacuum deposition method. With this configuration, the cathode 16 is formed.

Although not shown in FIGS. 2A to 2E, for the purpose of suppressing a situation in which each finished functional layer is exposed to atmosphere, it is possible to further provide, on the surface of the cathode 16, an encapsulation layer or an encapsulation can that spatially isolates the entire organic EL element 10 from the outside. The encapsulation layer may be formed by using a material such as, for example, SiN (silicon nitride) or SiON (oxynitride silicon), and may be provided so as to encapsulate each functional layer therein. In the case of using the encapsulation can, the encapsulation can may be formed by using, for example, the same material as that of the substrate 11, and includes a getter provided within the enclosed space, the getter being for absorbing moisture and the like.

Through the steps described above, an organic EL element 10 as shown in FIG. 1 can be produced.

### [Al Content in Hole Injection Layer]

Various types of evaluation experiments performed to determine an appropriate deposition condition for forming the hole injection layer 13 will be described next with reference to FIGS. 3 to 7.

FIG. 3 is a diagram showing examples of Al content in the hole injection layer 13 according to the embodiment.

In the present embodiment, a hole injection layer 13 having a stable composition ratio can be obtained by performing deposition under a predetermined deposition condition. To be specific, a hole injection layer 13 was deposited by sputtering in a RF magnetron sputtering apparatus using an Al sputtering target and a MO sintered compact disposed above the Al sputtering target. At this time, the substrate temperature was not controlled, an argon gas or a mixed gas of an argon gas and an oxygen gas was used as the gas introduced into the chamber, the input power density was set to 1.23 W/cm², and an appropriate amount of NiO sintered compact was disposed. Furthermore, the amount of Al added was adjusted. Films A to E shown in FIG. 3 were thereby obtained.

FIG. 3 shows the Al content (the proportion of the number of Al atoms with respect to the total number of constituent atoms such as Ni, Al and O, also referred to as Al concentration) of each of the films A to E subjected to XPS (X-ray Photoelectron Spectroscopy) evaluation. The films A to E were evaluated in terms of light transmittance and hole injection efficiency.

### [Light Transmittance]

In order to cause the light emitted from the organic EL element 10 having a stack structure as shown in FIG. 1 to efficiently travel to the outside of the element, it is necessary to cause light to efficiently pass through the hole injection layer 13. This is effective not only for a bottom emission type organic EL element in which light is extracted from the anode 12 side of the organic EL element 10, but also for a top emission type organic EL element in which light is extracted from the cathode 16 side, for the purpose of effectively extracting the light reflected by the anode 12 from the cathode 16 side.

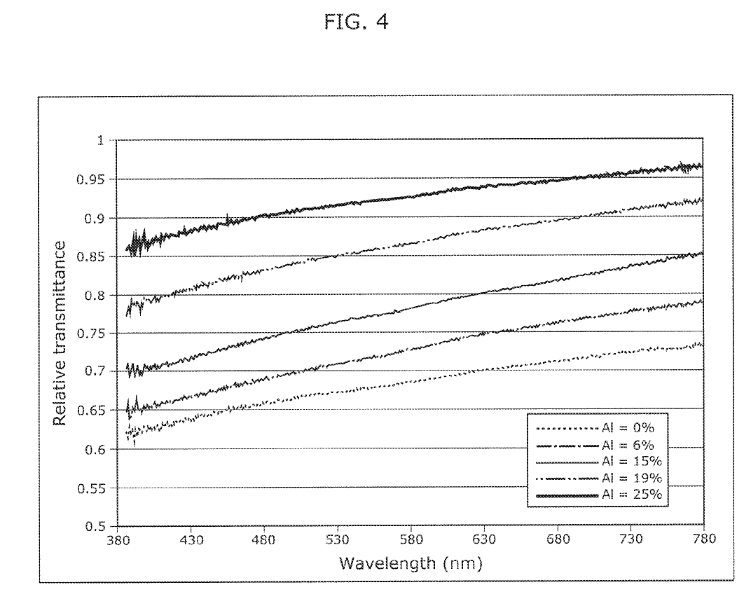

FIG. 4 is a diagram showing the transmittance of NiOₓ films having a thickness of 10 nm according to the embodiment.

As shown in FIG. 4, in a visible light band (about 380 nm to about 780 nm), as the amount of Al increases, the light transmittance of the NiOₓ film is improved accordingly. FIG. 4 shows the results of transmittance evaluation of the films A to E, except that a film having an Al content of 19% is used instead of the film C having an Al content of 10%.

The light transmittance of light that passes through a layer is highly dependent on the band gap of the material itself. In general, it is known that in a semiconductor that absorbs visible light such as NiOₓ, the absorption of visible light is suppressed more as the band gap increases, and as a result, the transmittance is improved. In the present embodiment, it is believed that the addition of Al to a NiOₓ film increases the band gap, as a result of which the light transmittance is improved.

As described above, in the organic EL element 10 according to the present embodiment, it is possible to enhance the light transmittance by adding Al to a transition metal oxide contained in the hole injection layer 13 as a main component, or to be specific, a nickel oxide. At this time, as shown in FIG. 4, the light transmittance can be enhanced more as the proportion of the number of Al atoms is greater with respect to the total number of all of the atoms constituting the hole injection layer 13. That is, the higher the Al content, the more the transmittance of visible light can be enhanced.

### [Configuration of Evaluation Device (Hole-Only Element)]

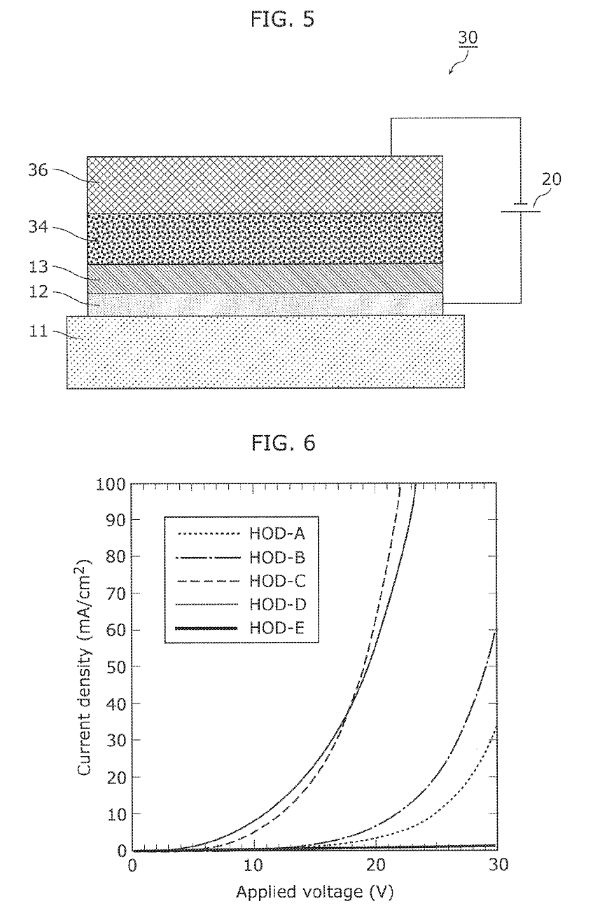

Next, in order to confirm the effectiveness of different Al contents in the hole injection layers 13 shown in FIG. 3, hole injection efficiency was evaluated by using hole-only elements 30 as shown in FIG. 5 as evaluation devices.

In an organic EL element in actual operation, carriers that form electric current are composed of both holes and electrons. Accordingly, not only a hole current, but also an electron current is reflected in the electric properties of the organic EL element.

However, in the hole-only element, because the injection of electrons from the cathode is inhibited, little electron current flows, and thus the total current is composed substantially of a hole current alone. In other words, the carriers can be regarded as being composed of holes alone, and thus the hole-only element is suitable for use in evaluation of hole injection efficiency.

A hole-only element 30 shown in FIG. 5 is different from the organic EL element 10 shown in FIG. 1 in that a buffer layer 34 and a cathode 36 are provided in place of the buffer layer 14 and the cathode 16 and that the light emitting layer 15 is not provided.

To be specific, the hole-only element 30 was configured such that an anode 12 made of a 50 nm thick ITO thin film, a hole injection layer 13 having a thickness of 10 nm and a composition ratio described above, a buffer layer 34 having a thickness of 200 nm and made of α-NPD, and a cathode 36 having a thickness of 100 nm and made of gold were stacked in sequence on a substrate 11.

Hereinafter, hole-only elements 30 obtained by using the films A to E shown in FIG. 3 as the hole injection layers 13 are respectively referred to as HOD-A, HOD-B, HOD-C, HOD-D and HOD-E.

### [Hole Injection Efficiency]

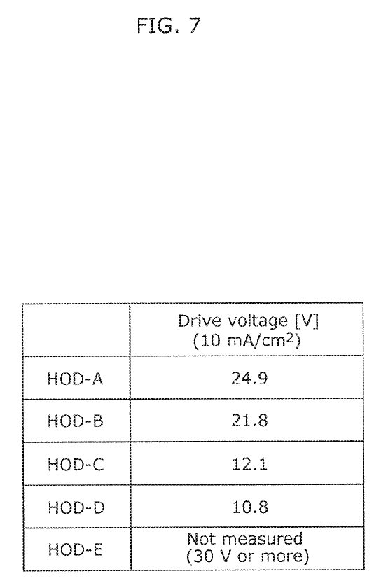

Each of the produced hole-only elements 30 was connected to a direct current power source 20, to which a voltage was applied. The applied voltage at this time was changed, and the current value of current flowing according to the voltage value was measured, which was then converted to a value (current density) per unit area of the hole-only element 30. The results of conversion are shown in FIGS. 6 and 7.

FIG. 6 is a device characteristics diagram showing a relationship between applied voltage and current density of the hole-only elements according to the embodiment. In FIG. 6, the vertical axis indicates current density (mA/cm2) and the horizontal axis indicates applied voltage (V).

FIG. 7 is a diagram showing drive voltages for different composition ratios of the hole injection layers included in the hole-only elements according to the embodiment. The word “drive voltage” in FIG. 7 refers to an applied voltage with a current density of 10 mA/cm², which is a practically usable value.

It can be said that the lower the drive voltage, the higher the hole injection efficiency of the hole injection layer 13. The reason is as follows.

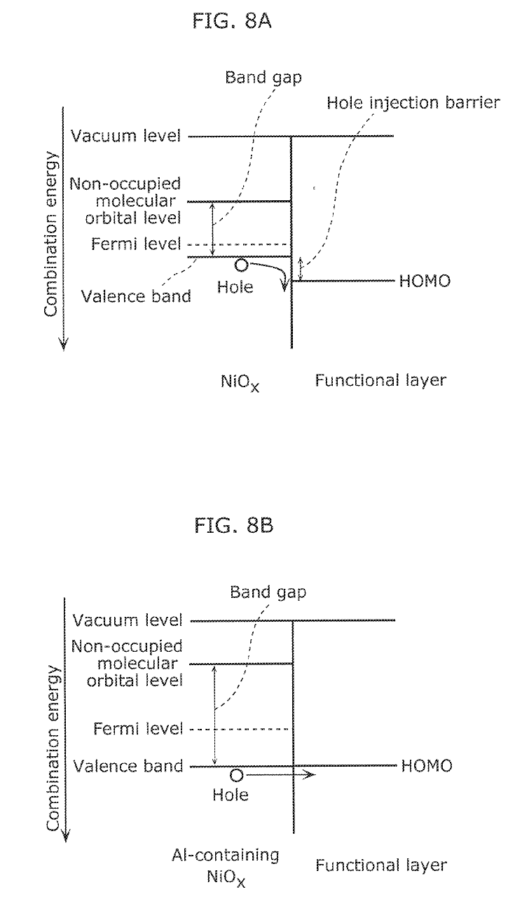

In the hole-only elements, portions other than the hole injection layer 13 are made in the same method, and it is therefore considered that the hole injection barrier between two adjacent layers excluding the hole injection layer 13 is constant. Also, another experiment was conducted, and a low-resistance ohmic contact was observed at the bond interface between the anode 12 and the hole injection layer 13 used in this experiment irrespective of the deposition condition, and it is therefore considered that the hole injection efficiency at this interface is very high. Accordingly, it can be said that the differences in drive voltage due to the deposition condition for forming the hole injection layer 13 strongly reflect the hole injection efficiency for injecting holes from the hole injection layer 13 to the buffer layer 34. The mechanism that reduces the hole injection barrier at this interface will be described later with reference to FIGS. 8A and 8B.

As shown in FIGS. 6 and 7, HOD-B, HOD-C and HOD-D have a better hole injection efficiency than HOD-A and HOD-E. Also, although not shown in the diagrams, the following result was obtained: the injection efficiency of the hole injection layer having an Al content of 20% was higher than that of the hole injection layer (HOD-A) having an Al content of 0%. That is, the hole injection layer having an Al content that is greater than 0% but not greater than 20% has a higher hole injection efficiency than the hole injection layer having an Al content of 0%.

On the other hand, as shown in FIGS. 6 and 7, HOD-E has a lower hole injection efficiency than HOD-A, That is, the hole injection layer having an Al content of 25% or greater has a lower hole injection efficiency than the hole injection layer having an Al content of 0%.

As described above, the hole injection efficiency can be enhanced by setting the number of Al atoms contained in the hole injection layer to be greater than 0% of the total number of atoms constituting the hole injection layer, preferably 20% or less, and more preferably 15% or less.

### [Hole Injection Efficiency and Band Gap]

As described above, by addition of Al, the band gap of the NiOₓ film increases. Here, the increase of the band gap, or in other words, the phenomenon in which the energy level such as the valence band moves away from the Fermi level is synonymous with an increase in the combination energy of the valence band.

FIG. 8A conceptually shows an energy diagram at an interface between a functional layer (buffer layer 14) and a NiOₓ film (hole injection layer 13) that does not contain Al. FIG. 8B conceptually shows an energy diagram at an interface between a functional layer (buffer layer 14) and a NiOₓ film (hole injection layer 13) that contains Al.

As shown in FIG. 8A, there is a difference in energy level between the valence band of the NiOₓ film and the HOMO of the functional layer. This difference is the hole injection barrier of the holes injected from the NiOₓ film, which is the cause of the reduction of the injection efficiency.

As can be seen from the comparison between FIG. 8A and FIG. 8B, as a result of the NiOₓ film containing Al, the band gap increases. Thus, the valence band of the NiOₓ film approaches relatively close to the HOMO of the functional layer, and the hole injection barrier formed between these levels is therefore reduced.

On the other hand, Al in the form of an oxide is insulative, and thus the addition of an excess amount of Al increases the resistance of the hole injection layer 13 itself and increases the drive voltage to a high voltage level. For this reason, as shown in FIGS. 6 and 7, the drive voltage increases significantly when the Al content is 20% or greater, and therefore it can be said that the addition of Al at a concentration lower than 20% is preferable for improvement of the hole injection efficiency.

Also, a similar transmittance improving effect that maintains hole injection efficiency can be applied not only to Ni but also to all transition metal oxides. To be specific, the transition metal of the transition metal oxide contained in the hole injection layer 13 as a main component is at least one of Sc, Ti, V, Cr, Mn, Fe, Co, Cu, Zr, Hf, Nb, Ta, Mo and W. At this time, the transition metal may be a mixture of two or more of these metals.

### [Summation]

The evaluation of hole injection efficiency has been described above by way of the evaluation results obtained by using the hole-only element 30, rather than using the organic EL element 10, but the hole-only element 30 has the same configuration as the organic EL element 10 for use in actual operation (FIG. 1) except for the buffer layer 34, the cathode 36 and the light emitting layer 15. Accordingly, in the organic EL element 10, the dependency of the hole injection efficiency for injecting holes from the anode 12 to a functional layer such as the buffer layer 14 on the deposition condition is inherently the same as that of the hole-only element 30.

In other words, it has been confirmed that the use of the film B, the film C or the film D as the hole injection layer 13 improves the hole injection efficiency for injecting holes from the hole injection layer 13 to the buffer layer 14, and low-voltage driving is thereby achieved.

It is possible to use a RF magnetron sputtering apparatus that is different from the RF magnetron sputtering apparatus used in the present experiment described above. In this case, by adjusting the input power used in the deposition of the films A to E according to the size of a magnet on the back of the target such that the input power density satisfies the above-described condition, as in the present experiment, the hole injection layer 13 containing NiOₓ as a main component and having an excellent hole injection efficiency can be formed. Note that the total pressure and the oxygen partial pressure are not dependent on the apparatus, the target size and the target magnet size.

Also, at the time of deposition of the hole injection layer 13 by a sputtering method, the substrate temperature is intentionally not set in the sputtering apparatus installed in a room temperature environment. Accordingly, the substrate temperature at least before deposition is room temperature. However, the substrate temperature may rise during deposition by about 10° C.

From the foregoing, the organic EL element 10 preferably includes the film B, the film C or the film D as the hole injection layer 13 so as to achieve low-voltage driving. That is, as a result of the hole injection layer 13 according to the present embodiment including a transition metal oxide as a main component and containing Al, the hole injection efficiency can be enhanced, and the light transmittance can be enhanced.

At this time, the Al content is 20% or less, and preferably 15% or less. With this configuration, it is possible to suppress an increase in the resistance of the hole injection layer 13 and suppress the reduction of the hole injection efficiency. Accordingly, it is possible to enhance the hole injection efficiency while enhancing the light transmittance.

### [Relationship Between Al and Mg]

As described above, in the present embodiment, an example has been described in which the hole injection layer 13 includes a transition metal oxide as a main component and contains Al, but the hole injection layer 13 may contain Mg instead of Al. That is, the hole injection layer 13 contains only Mg among Al and Mg, and does not have to contain Al. Hereinafter, a description will be given to illustrate that the same effects as described above can be obtained when Al is replaced with Mg.

It is considered that a NiOₓ film containing Al (in other words, hole injection layer 13) has a mixed state of Al₂O₃ and NiO having a stable crystal structure. Accordingly, it is considered that the magnitude of insulation of the NiOₓ film containing Al is dependent on the volume ratio of insulative Al₂O₃ and conductive NiO.

Likewise, it is considered that a NiOₓ film containing Mg has a mixed state of NiO and MgO, and the magnitude of insulation is dependent on the volume ratio of insulative MgO and conductive NiO.

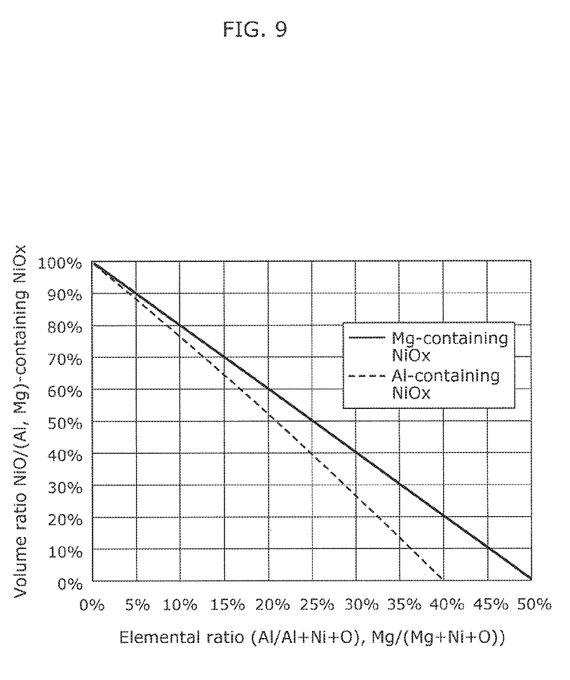

FIG. 9 is a diagram showing a relationship between elemental ratio and volume ratio of the NiOₓ film containing Al and the NiOₓ film containing Mg.

As shown in FIG. 9, the volume of NiO when the Al content is 20% is about 52%. The same insulation (volume ratio) is obtained when the Mg content is about 24%.

Also, the volume of NiO when the Al content is 15% is about 65%. The same insulation (volume ratio) is obtained when the Mg content is about 18%.

From the foregoing, an Al content of “20% or less” at which good hole injection properties can be obtained corresponds to a Mg content of “24% or less”. Likewise, an Al content of “15% or less” at which good hole injection properties can be obtained corresponds to a Mg content of “18% or less”.

It is also possible to form a hole injection layer by using a NiO film containing both Mg and Al. As shown in FIG. 9, an Al content of 5% corresponds to a Mg content of 6%. That is, the Mg content can be converted to the Al content by multiplying the Mg content by 5/6.

Accordingly, for example, the NiO film containing both Mg and Al may satisfy the following relationship: x+(5/6)×y≦20, where the Al content is represented by x, and the Mg content is represented by y. Also, preferably, the NiO film containing both Mg and Al may satisfy the following relationship: x+(5/6)×y≦15.

### Other Embodiments

The organic EL element according to one or more aspects has been described above by way of embodiments, but the present disclosure is not limited to the embodiments. Embodiments obtained by making various modifications that can be conceived by a person having ordinary skill in the art to the embodiments described above without departing from the scope of the present disclosure as well as embodiments obtained by combining structural elements of different embodiments are also encompassed by the scope of the present disclosure.

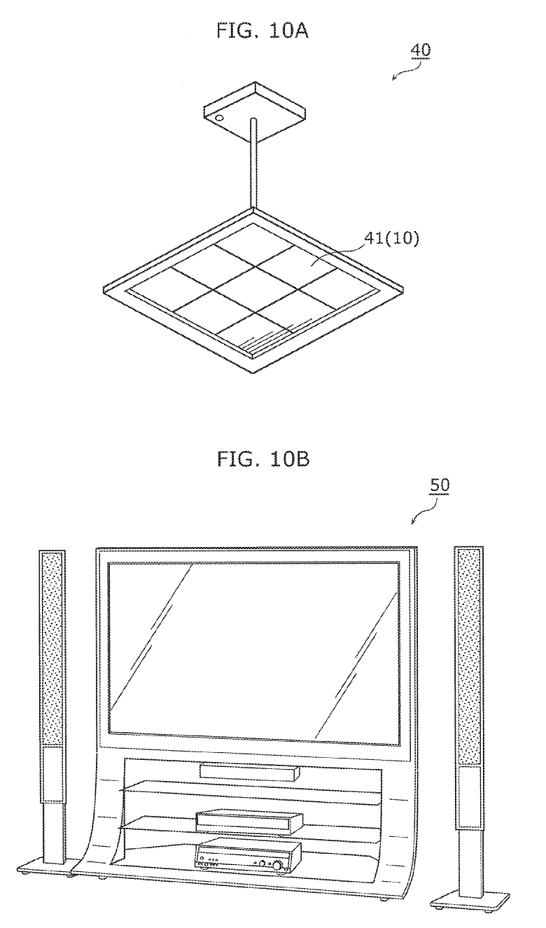

(1) For example, the organic EL element according to one aspect of the present disclosure is not limited to a configuration in which the element is used alone. It is also possible to form an organic EL light emitting apparatus by integrating a plurality of organic EL elements as pixels on a substrate. Such an organic EL light emitting apparatus can be implemented by setting the thicknesses of the layers in the elements as appropriate, and can be used as, for example, a lighting apparatus 40 shown in FIG. 10A, or the like.

The lighting apparatus 40 shown in FIG. 10A includes organic EL elements 10 as described above. For example, the lighting apparatus 40 includes a light emitting unit 41 in which a plurality of organic EL elements 10 are arranged adjacent to each other. The light emitting unit 41 is protected by a light fixture casing covering the edge of the light emitting unit 41 and is configured to be suspended from a ceiling. The lighting apparatus 40 does not need to be configured to be suspended from a ceiling, and may be configured to be installed on a wall.

(2) It is also possible to form an organic EL panel in which a plurality of organic EL elements 10 corresponding to red, green and blue pixels are arranged. In the case of forming a light emitting layer corresponding to each pixel through an application step such as an ink jet method, it is desirable to provide a bank that defines each pixel on the hole injection layer 13. As a result of providing banks, it is possible to prevent inks made of light emitting layer materials of respective colors from being mixed together in the application step.

Here, as a bank forming step, for example, a method can be used in which a bank material made of a photosensitive resist material is applied onto the surface of a hole injection layer 13, which is then pre-baked and exposed to light by using a pattern mask, washed with a developing solution so as to remove an uncured and unnecessary bank material, and finally cleaned with pure water. The present disclosure is applicable to a hole injection layer 13 made of a metal oxide that has undergone such a bank forming step. Also, the organic EL panel is also applicable to a display apparatus 50 shown in FIG. 10B. The display apparatus 50 can be used as, for example, an organic EL display or the like.

(3) The organic EL element 10 according to one aspect of the present disclosure may be configured as a so-called bottom emission type organic EL element, or may be configured as a so-called top emission type organic EL element. Also, the organic EL element 10 may be configured as a double-sided light emission type organic EL element.

(4) The organic EL element 10 according to one aspect of the present disclosure has been described as having, for example, a configuration in which the anode 12 is provided on the substrate 11, but the present disclosure is not limited thereto. A configuration is also possible in which the cathode 16 is provided on the substrate 11, and the anode 12 is provided at a position opposed to the substrate 11 across the cathode 16.

Also, various modifications, replacements, additions, omissions and the like may be made on the embodiments described above within the scope of the claims and the scope equivalent thereto.

### INDUSTRIAL APPLICABILITY

The organic EL element and the organic EL light emitting apparatus according to the present disclosure are preferably used in, for example, organic EL light emitting apparatuses used as various types of display apparatuses, television apparatuses, displays for portable electronic devices that are for consumer use, public institutional use or commercial use.

### REFERENCE SIGNS LIST

10 organic EL element
11 substrate
12 anode
13 hole injection layer
14, 34 buffer layer (functional layer)
15 light emitting layer (functional layer)
16, 36 cathode
20 direct current power source
30 hole-only element
40 lighting apparatus
41 light emitting unit
50 display apparatus

1. An organic electroluminescent (EL) element comprising:
an anode and a cathode that are disposed at opposed positions; and
a functional layer and a hole injection layer that are stacked between the anode and the cathode, the functional layer containing an organic material, and the hole injection layer being for injecting holes into the functional layer,
wherein the hole injection layer includes a transition metal oxide as a main component, and contains at least one of Al and Mg.

2. The organic EL element according to claim 1,
wherein the transition metal oxide is a nickel oxide, and
a number of Al atoms contained in the hole injection layer is 20% or less of a total number of atoms constituting the hole injection layer.

3. The organic EL element according to claim 2,
wherein the number of Al atoms contained in the hole injection layer is 15% or less of the total number of atoms constituting the hole injection layer.

4. The organic EL element according to claim 1,
wherein the transition metal oxide is a nickel oxide, and
a number of Mg atoms contained in the hole injection layer is 24% or less of a total number of atoms constituting the hole injection layer.

5. The organic EL element according to claim 4,
wherein the number of Mg atoms contained in the hole injection layer is 18% or less of the total number of atoms constituting the hole injection layer.

6. The organic EL element according to claim 1,
wherein the transition metal oxide contains transition metal that is at least one of Sc, Ti, V, Cr, Mn, Fe, Co, Ni, Cu, Zr, Hf, Nb, Ta, Mo and W.

7. The organic EL element according to claim 1,
wherein the organic material is an amine material.

8. The organic EL element according to claim 1,
wherein the functional layer includes at least one of a hole transporting layer that transports the holes, a light emitting layer that emits light by recombination of the holes and electrons, and a buffer layer that is used to adjust optical characteristics or block electrons.

9. An organic EL light emitting apparatus comprising the organic EL element according to claim 1.
